(19) United States
(12) Patent Application Publication
(10) Pub. No.: US 2017/0112022 A1
(43) Pub. Date: Apr. 20, 2017

(54) HEAT SINK AND ELECTRONIC APPARATUS

(71) Applicant: FUJITSU LIMITED, Kawasaki-shi (JP)

(72) Inventors: Hiromu SHOJI, Kawasaki (JP); Hiroshi NAKAMURA, Kawasaki (JP)

(21) Appl. No.: 15/249,022

(22) Filed: Aug. 26, 2016

(30) Foreign Application Priority Data
Oct. 19, 2015 (JP) 2015-205395

(51) Int. Cl. H05K 7/20

(52) U.S. Cl. CPC H05K 7/20418; H05K 7/20336

(57) ABSTRACT

A heat sink includes: a base sheet metal having a flat plate shape; and a radiation fin bonded to a first surface of the base sheet metal, wherein the radiation fin includes: a bonding plate portion having a flat plate shape, and superposed on and bonded to the first surface of the base sheet metal; and a fin member installed upright with respect to the bonding plate portion, and wherein the base sheet metal and the bonding plate portion are bonded to each other by fitting a convex portion, which is formed on one of the base sheet metal and the bonding plate portion, into a concave portion formed on a remaining one thereof through half-punch working,

### CROSS-REFERENCE TO RELATED APPLICATION

This application is based upon and claims the benefit of priority of the prior Japanese Patent Application No 2015-205395, filed on Oct. 19, 2015, the entire contents of with are incorporated herein by reference,

### FIELD

The embodiment's discussed herein are related to a heat sink and an electronic apparatus.

### BACKGROUND

A heat sink is known as a cooling device for cooling an electronic part mounted in an electronic apparatus. The heat sink is installed to be in thermal contact with the electronic part, and cools the electronic part by dissipating heat of the electronic part from a cooling fin.

As one form of heat sink, a sheet metal type heat sink is widely used which is formed by bonding a radiation fin to a sheet metal. The sheet metal type heat sink has an advantage in that it is easy to achieve a reduction in weight. In the sheet metal type heat sink, the bonding of the sheet metal and the radiation fin may be performed by a bonding method through caulking that presses and deforms, for example, a rivet inserted through a preformed hole. In addition, there is a bonding method of bonding a sheet metal and a radiation fin to each other by forming a slit (an incision) in one surface of the sheet metal in advance, and inserting the radiation fin into the slit.

However, in the case where the bonding method through caulking is employed in the sheet metal type heat sink, it is difficult to ensure waterproofness because water leaks from the through hole that penetrates the sheet metal and the radiation fin. That is, in this case, it is difficult to use the sheet metal type heat sink in a part of a case of a waterproof electronic apparatus. Meanwhile, in the case of the bonding method that inserts the radiation fin into the slit formed in the sheet metal, the radiation fin and the sheet metal are in linear contact with each other so that a heat transfer quantity from the sheet metal to the radiation fin is small, which easily deteriorates the diffusion efficiency. Further, in order to increase the heat transfer quantity, it is necessary to secure a sufficient slit depth by securing the thickness of the sheet metal, which makes it difficult to achieve the reduction in weight.

The following are reference documents.
[Document 1] Japanese Laid-Open Patent Publication No. 2007-180369 and
[Document 2] Japanese Laid-Open Patent Publication No. 2009-218603.

### SUMMARY

According to an aspect of the invention, a heat sink includes: a base sheet metal having a flat plate shape; and a radiation fin bonded to a first surface of the base sheet metal, wherein the radiation fin includes: a bonding plate portion having a flat plate shape, and superposed on and bonded to the first surface of the base sheet metal; and a fin member installed upright with respect to the bonding plate portion, and wherein the base sheet metal and the bonding plate portion are bonded to each other by fitting a convex portion, which is formed on one of the base sheet metal and the bonding plate portion, into a concave portion formed on a remaining one thereof through half-punch working.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of an electronic apparatus according to an exemplary embodiment;

FIG. 2 is a perspective view illustrating the rear side of a heat sink detached from a waterproof case according to the exemplary embodiment;

FIG. 3 is a perspective view of the heat sink according to the exemplary embodiment;

FIG. 4 is a plan view of heat spreader according to the exemplary embodiment;

FIG. 5 is a perspective view of the heat spreader according to the exemplary embodiment;

FIG. 6 is a sectional view taken in the arrow direction of A-A′ in FIG. 4;

FIG. 7 is a sectional view taken in the arrow direction of B-B′ in FIG. 4;

FIG. 8 is a view illustrating a method of manufacturing a heat spreader according to the exemplary embodiment;

FIG. 9 is a view for explaining a bonding structure of a base sheet metal and a radiation fin in the heat sink according to the exemplary embodiment; and

FIG. 10 is a view illustrating a placing pattern of a half punch bonded portion in the heat sink according to the exemplary embodiment.

### DESCRIPTION OF EMBODIMENT

Hereinafter, art exemplary embodiment of a heat sink and an electronic apparatus will be described with reference to the accompanying drawings.

### Exemplary Embodiment

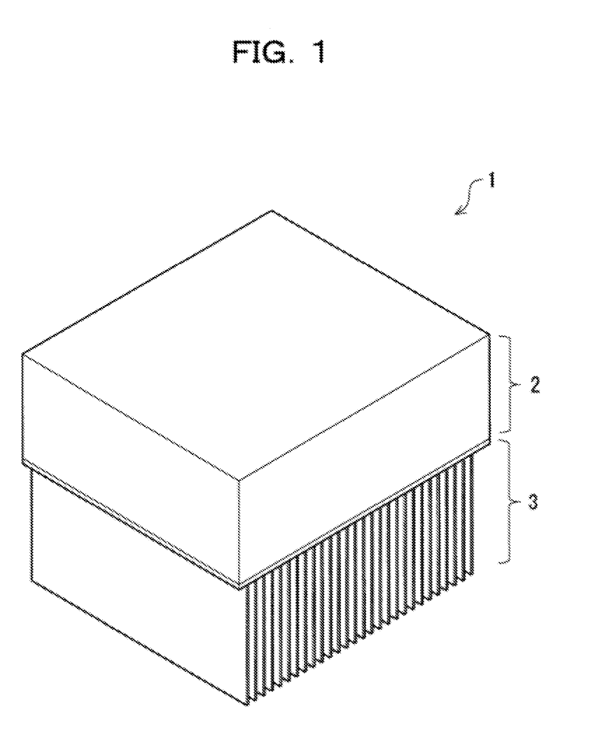

FIG. 1 is a perspective view of an electronic apparatus 1 according to an exemplary embodiment The electronic apparatus 1 includes a waterproof case 2 and a heat sink 3. The waterproof case 2 refers to a waterproof case that has an appearance of a one side-opened rectangular parallelepiped. The heat sink 3 is attached to the waterproof case 2 to block the opened side of the waterproof case 2. For example, a packing (not illustrated) is located at a bonded portion between the heat sink 3 and the waterproof case 2 such that the heat sink is formed in a watertight structure. In addition, various devices may be applied as the electronic apparatus 1, and for example, a measurement device, a power source device, or an industrial camera may be applied. In addition, the waterproof case 2 may be a so-called shield case.

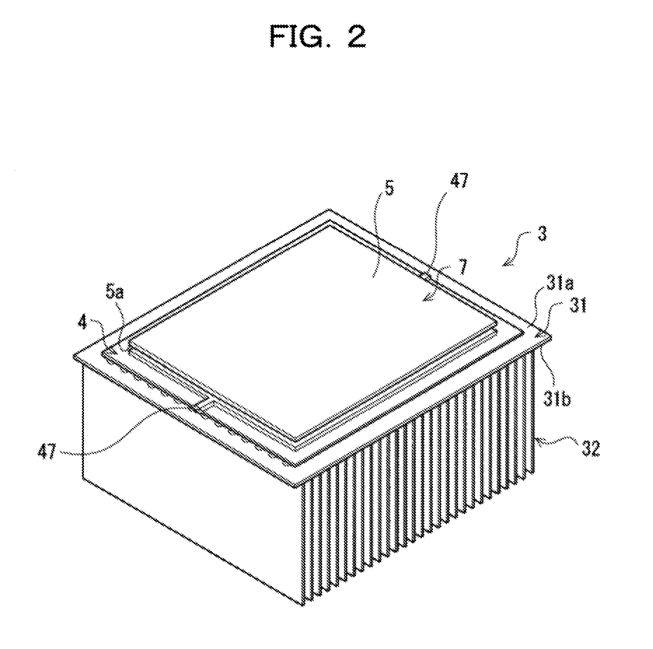

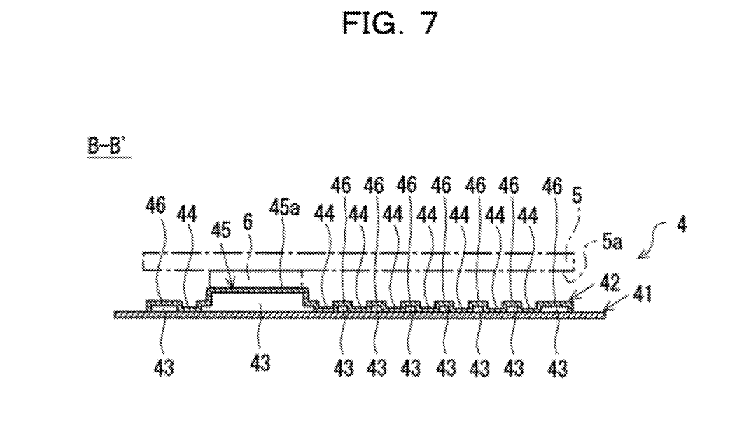

FIG. 2 is a perspective view illustrating the rear side of the heat sink 3 detached from the waterproof case 2 according to the exemplary embodiment. The heat sink 3 is a sheet metal type heat sink. The heat sink 3 includes a base sheet metal 31 having a flat plate shape, a radiation fin 32 bonded to a first major surface 31a of the base sheet metal 31, and a heat spreader 4 attached to a second major surface 31b of the base sheet metal 31. The heat sink 3 is provided with a plurality of radiation fins 32, and the radiation fins 32 are installed upright to be perpendicular to the base sheet metal 31. Reference numeral 5 indicates a board. An electronic part 6 (see FIG. 7) is mounted on a mounting surface 5a of the board 5. Hereinafter, the board 5 and the electronic part 6 mounted on the board 5 will be collectively referred to as a board unit 7. In the present exemplary embodiment, the first major surface 31a is an example of a first surface, and the second major surface 31b is an example of a second surface.

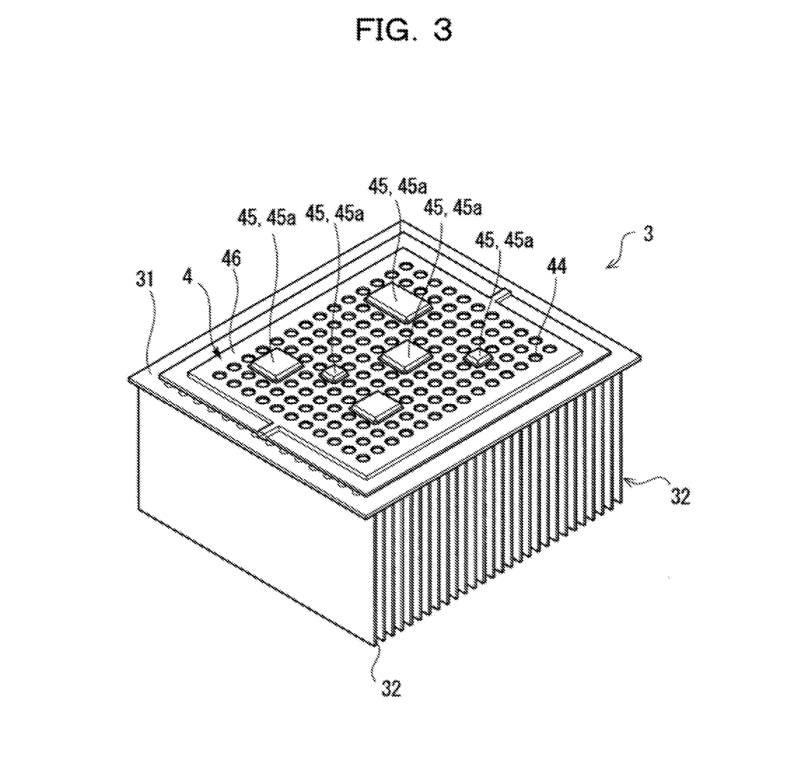

FIG. 3 is a perspective view illustrating the rear side of the heat sink 3 according to the exemplary embodiment, and the illustration of the board unit 7 is omitted. The heat sink 3 (the time sheet metal 31 and the radiation fins 32) and the heat spreader 4 are formed of, for example, a metal having an excellent thermal conductivity such as aluminum. The heat spreader 4 is integrally bonded to the base sheet metal 31. In the present exemplary embodiment, the heat spreader 4 and the base sheet metal 31 are bonded to each other via diffusion bonding. The diffusion bonding is a technique of bringing metal materials to be bonded into close contact with each other and applying pressure and heat to the metal materials in, for example, a vacuum or inert gas atmosphere, thereby bonding the metal materials to each other at an atomic level using the diffusion of atoms generated in the bonding surfaces of the metal materials. However, the bonding method of the heat spreader 4 and the base sheet metal 31 is not limited to the diffusion bonding, and may be performed via, for example, deposition bonding.

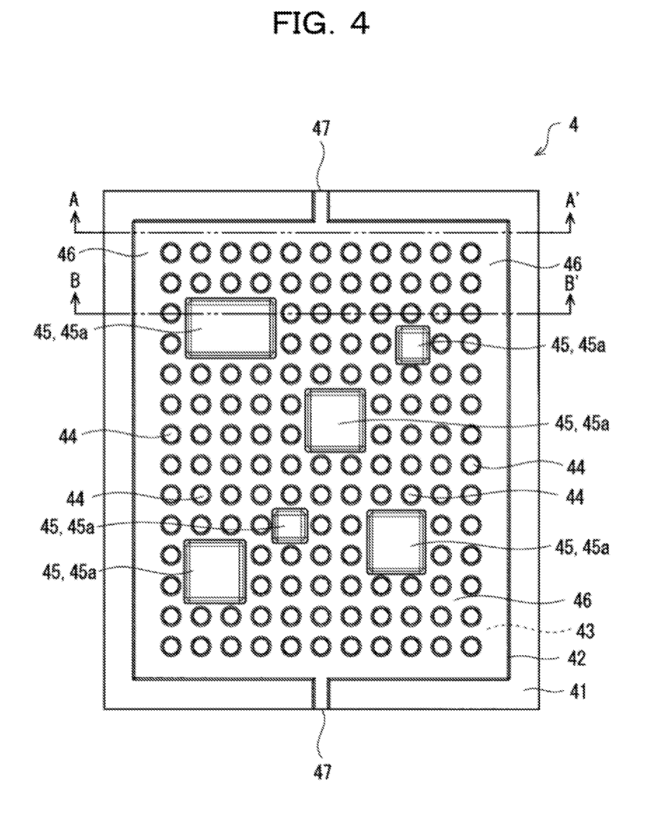

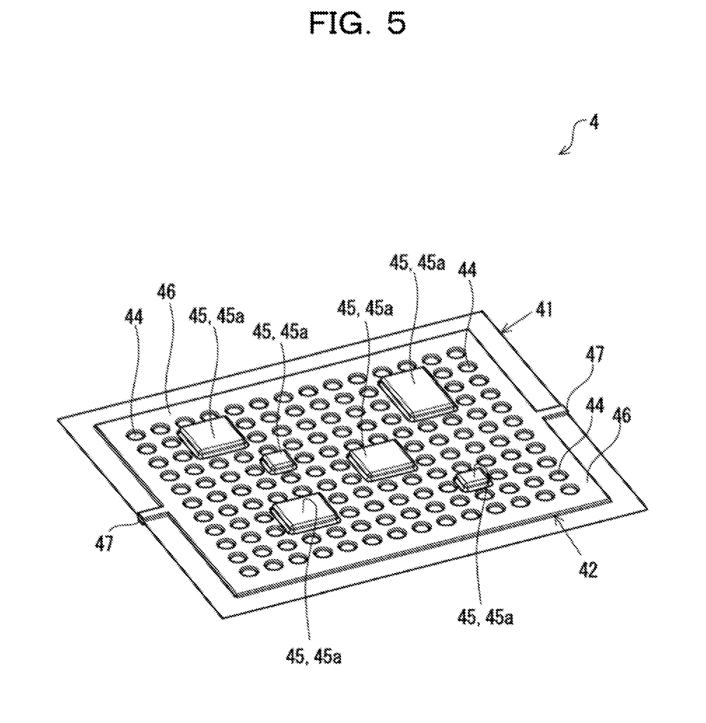

FIGS. 4 and 5 are views illustrating he heat spreader 4 according to the exemplary embodiment. FIG. 4 is a plan view of the heat spreader 4 according to the exemplary embodiment FIG. 5 is a perspective view of the heat spreader 4 according to the exemplary embodiment. The heat spreader 4 is formed by bonding two aluminum plates 41 and 42 to each other. Hereinafter, the plate indicated by reference numeral 41 will be referred to as a first plate, and the plate indicated by reference numeral 42 will be referred to as a second plate. Each of the first plate 41 and the second plate 42 has a substantially rectangular plane, and the first plate 41 is one size larger than the second plate 42. However, the shapes of the first plate 41 and the second plate 42 are not particularly limited.

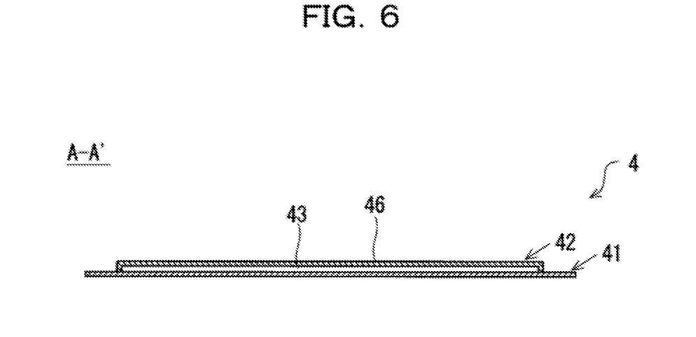

FIG. 6 is a sectional view taken in the arrow direction of A-A′ in FIG. 4. FIG. 7 is a sectional view taken in the arrow direction of B-B′ in FIG. 4. The second plate 42 is bonded to the first plate 41 so that a hollow inner space 43 is formed between the first plate 41 and the second plate 42.

In addition, in FIGS. 4 and 5, reference numeral 44 indicates “close contact area portions” in which the inner surfaces of the first plate 41 and the second plate 42 are bonded to each other in a close contact state. In the bonded planar area between the first plate 41 and the second plate 42, the plurality of close contact area portions 44 are regularly arranged at a constant interval in the longitudinal and transverse directions. Meanwhile although each close contact area portion 44 is of a circular shape in the present exemplary embodiment, the planar shape of the close contact area portion 44 is not limited thereto. In addition, the number the close contact area portions 44 or the planar arrangement pattern of the close-contact area portions 44 may also be appropriately changed.

In the bonded planar area of the first plate 41 and the second plate 42, the portion other than the close contact area portions 44 is formed with the above-described hollow inner space 43 by causing the inner surfaces of the first plate 41 and the second plate 42 to be spaced apart from each other.

Reference numeral 45 indicates “electronic part mounting portions on each of which an electronic part 6 is placed. In addition, the reference numeral 46 indicates a “common raised portion.” White the electronic part mounting portions 45 are formed at six locations in the present exemplary embodiment, the number, positions, and sizes the electronic part mounting portion are not particularly limited. The number, positions, and sizes of the electronic part mounting portions 45 only need to correspond to the number, positions, and sizes of the electronic parts 6 to be mounted on the mounting surface 5a of the board 5. In addition, the shapes of the electronic part mounting portions 45 are not particularly limited. The electronic part mounting portions 45 are further raised, as compared to the common raised portion 46 (see, e.g., FIG. 3). Each electronic part mounting portion 45 has a flat mounting surface 45a, and the electronic part 6 may be mounted on the placing surface 45a.

in the present embodiment, the heat spreader 4 functions as a so called heat pipe as a fluid refrigerant (e.g., water) is encapsulated in the inner space 43. That is, the inner space 43 function as a flow path through which the refrigerant flows. Hereinafter, the inner space 43 encapsulated with the refrigerant will be referred to as a “refrigerant encapsulation portion 43.”

Each electronic part mounting portion 45 of the heat spreader 4 receives heat emitted from the electronic part 6 mounted on the mounting surface 45a, and exchanges heat with the refrigerant encapsulated in the refrigerant encapsulation portion 43. As a result, the electronic part 6 is cooled as the refrigerant takes the heat from the electronic part 6. Meanwhile, the refrigerant, which is heated by taking the heat from the electronic part 6, evaporates within the electronic part mounting portion 45 (the refrigerant enclosure portion 43). The vapor of the refrigerant generated in the electronic part mounting portion 45 is cooled and condensed in the press of being transported from the refrigerant encapsulating portion 43 to the common raised portion 46 side, thereby being turned into a liquid again. By the movement of latent heat resulting from the evaporation and condensation, the heat taken from the electronic parts 6 in the electronic part mounting portions 45 may be efficiently and evenly diffused in the planar direction of the heat spreader 4.

In addition, the heat evenly diffused in the planar direction of the heat spreader 4 is transferred from the first plate 41 of the heat spreader 4 to the base sheet metal 31 of the heat sink 3. The first plate 41 has a flat surface and is in plane contact with and bonded to the base sheet material 31 such that heat may be efficiently conducted from the first plate 41 to the base sheet metal 31 of the heat sink 3. In addition, the heat transferred to the base sheet metal 31 of the heat sink 3 is transferred to the radiation fins 32 bonded to the first major surface 31a of the base sheet metal 31, and dissipated from the radiation fins 32 into the air. Accordingly, the cooling of the electronic part 6 may be efficiently performed.

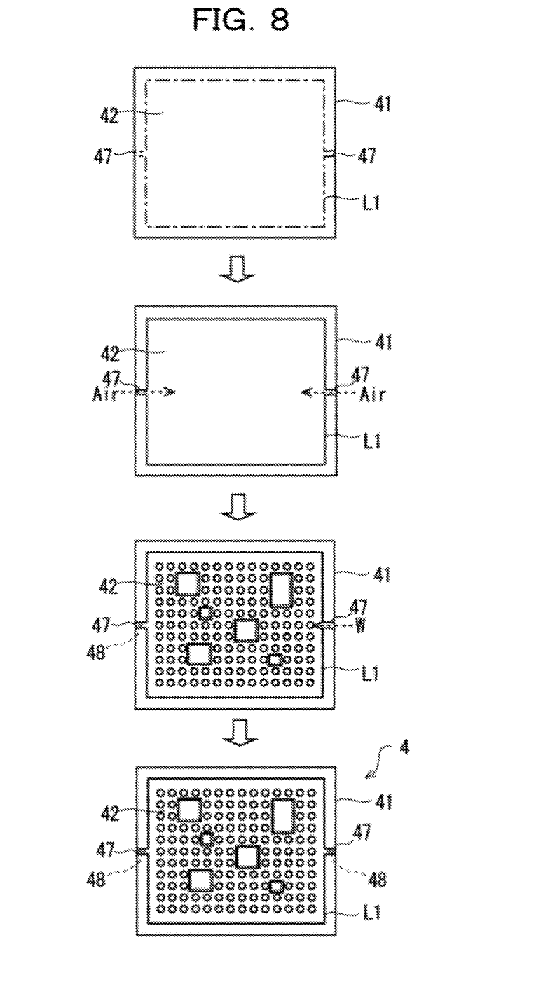

FIG. 8 is a view illustrating a method of manufacturing the heat spreader 4 according to the exemplary embodiment First, the second plate 42 is bonded to the first plate 41. More specifically, the second plate 42 is bonded to the first plate 41 along the contour line L1 of the second plate 42 (represented by the long and short dashed line in FIG. 8) while leaving openings 47 at predetermined positions. While the openings 47 are formed at two positions in the present exemplary embodiment, the number or positions of the openings 47 are not particularly limited.

Subsequently, air is introduced from the openings 47 to raise the second plate 42 with respect to the first plate 41. Accordingly, the second plate 42 swells in the direction where the bonded surfaces of the first plate 41 and the second plate 42 are spaced apart from each other so that the inner space 43 is formed. The introduction of air from the openings 47 may be performed in a state in which molds are disposed outside the first plate 41 and the second plate 42. In addition, the mold disposed at the second plate 42 side may be formed with concave portions which correspond to the electronic part mounting portions 45 and the common raised portion 46, and convex portions to form the close contact area portions 44. When the air is introduced through the openings 47, the second plate 42 swells along the concave portions formed in the mold so that the electronic part placing portions 45 and the common raised portion 46 are formed. In addition, since the swelling of the second plate 42 is restricted by the convex portions formed on the mold, the close contact area portions 44 are formed.

After the heat spreader 4 is molded, in a state in which one of the air introduction openings 47 is sealed by a sealing material 48, the fluid refrigerant (e.g., water) W is supplied into the inner space 43 from the other of the air introduction openings 47. After the introduction of the refrigerant into the inner space 43 is competed, the other air introduction opening 47 is sealed by the sealing material. Accordingly, the encapsulation of the refrigerant W into the inner space (refrigerant encapsulating portion) 43 in the heat spreader 4 is completed so that the heat spreader 4 is completed.

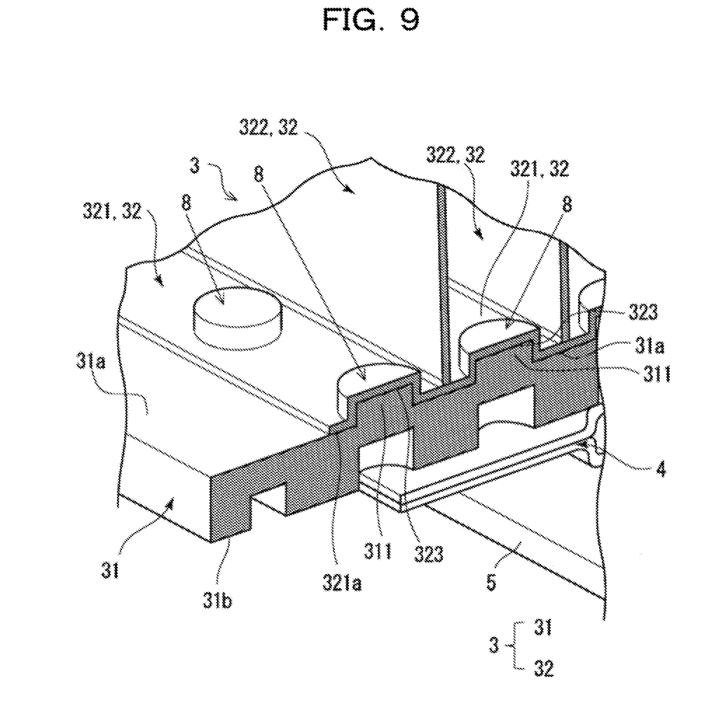

Subsequently, the detailed structure of the heat sink 3 will be described. FIG. 9 is a view for explaining the bonding structure of the base sheet metal 31 and the radiation fins 32 in the heat sink 3 according to the exemplary embodiment. As illustrated in FIG. 9, each radiation fin 32 includes a flat plate-shaped bonding plate portion 321 which is superposed and bonded onto the first major surface 31a of the base sheet metal 31, and a plurality of fin members 322 installed upright on the bonding plate portion 321. In the present exemplary embodiment, the plurality of fin members 322 are installed vertically upright on the bonding plate portion 321 at a constant interval.

In the heat sink 3, the base sheet metal 31 and the bonding plate portion 321 of each radiation fin 32 are bonded to each other by fitting a convex portion formed on one of the base sheet metal 31 and the bonding plate portion 321 into a concave portion formed on the other one through half-punch working. Half-punch working is so-called half-blanking working. In the example illustrated in FIG. 9, in the state in which each bonding plate portion 321 is stacked and superposed on the first major surface 31a of the base sheet metal 31, the half-punch working is performed by pressing a punch (not illustrated) from the second major surface 31b side of the base sheet metal 31. That is, convex portions 311 are formed by pushing the punch (not illustrated) from the second major surface 31b side of the base sheet metal to approximately half the thickness of the base sheet metal 31 so that the first major surface 31a of the base sheet metal 31 is raised.

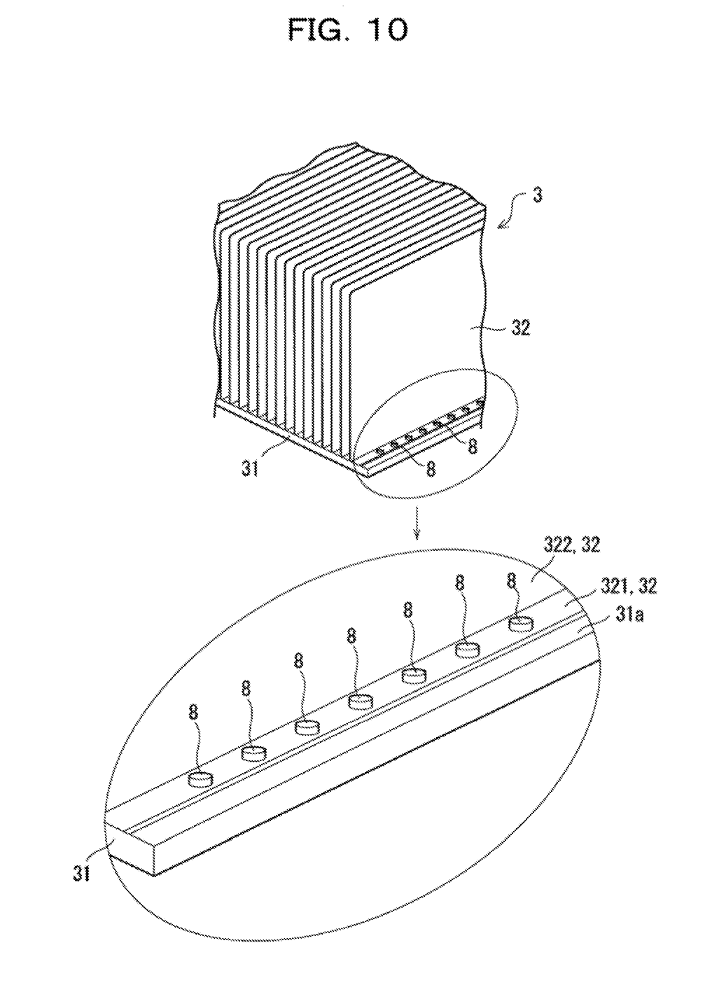

In the drawing, reference numeral 321a indicates “the sheet metal side facing surface” of the bonding plate portion 321. The sheet metal side surface 321a of the bonding plate portion 321 refers to the surface on the side that faces the first major surface 31a of the base sheet metal 31. When the convex portions 311 are formed on the first major surface 31a of the base sheet metal 31 as described above, the bonding plate portions 321 of the radiation fin 32 superposed on the first major surface 31. As a are deformed along the raised portions of the base sheet metal 31. As a result, as illustrated in FIG. 9, concave portions 323 are formed on the sheet metal side facing surface 321a of the bonding plate portion 321, and the convex portions 311 of the base sheet metal 31 are fitted onto the concave portions 323, respectively. Then, the convex portions 311 are fixed to the concave portions 323 by contact resistance between the convex portions 311 of the base sheet metal 31 and the concave portions 323 of the bonding plate portion 321. As a result, in the heat sink 3, the base sheet metal 31 and the bonding plate portions 321 of the radiation fin 32 are integrally bonded to each other. Each of the bonded portions formed by fitting the convex portions 311 of the base sheet metal 31 onto the concave portions 323 of the bonding plate portion 321 will be referred to as a “half-punch bonded portion 8”. As illustrated in FIG. 10, the half-punch bonded portions 8 may be arranged at regular intervals along the radiation fin 32. However, the arrangement pattern of the half-punch bonded portions 8 may be changed appropriately.

As described above, in the heat sink 3 according to the present exemplary embodiment, the base sheet metal 31 and the radiation fins 32 may be bonded to each other by the half-punch bonded portions 8 without forming a through-hole in the base sheet metal 31. Accordingly, because the inside of the base sheet metal 31 of the heat sink 3 (i.e. the heat spreader 4 side) and the space outside the base sheet metal 31 of the heat sink 3 (i.e. the radiation fin 32 side) are blocked from each other, water may be suppressed from entering the inside of the waterproof case 2 from the outside through the heat sink 3. That is, the waterproofness of the heat sink 3 may be ensured. In addition, because no slit needs to be formed for bonding the radiation fin 32 to the base sheet metal 31, the thickness of the base sheet metal 31 may be reduced, which may facilitate the weight reduction of the heat sink 3.

In addition, because the heat sink 3 includes the heat spreader 4, which is inserted between the electronic part 6 mounted on the board 5 and the base sheet metal 31, the thickness of the base sheet metal 31 may be reduced. In this case, a sufficient quantity of heat may be transferred from the base sheet metal 31 to the radiation fin 32, which may improve diffusion efficiency. Because the heat spreader 4 includes the refrigerant encapsulation portion 43 in which the fluid refrigerant W is encapsulated, the heat transfer quantity from the base sheet metal 31 to the radiation fin 32 may be remarkably increased and thus diffusion efficiency may be improved. Accordingly, the heat sink 3 may be implemented which has a reduced weight and is excellent in waterproofness and diffusion efficiency.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention,

What is claimed is:

1. A heat sink comprising:
a base sheet metal having a flat plate shape; and
a radiation fin bonded to a first surface of the base sheet m
wherein the radiation fin includes:
a bonding plate portion having a flat plate shape, and superposed on and bonded to the first surface of the base sheet metal; and
a fin member installed upright with respect to the bonding plate portion, and
wherein the base sheet metal and the bonding plate portion are bonded to each other by fitting a convex portion, which is formed on one of the base sheet metal and the bonding plate portion, into a concave portion formed on a remaining one thereof through half-punch working.

2. The heat sink according to claim 1, further comprising:
a heat spreader installed between a second surface of the base sheet metal opposite to the first surface and an electronic part mounted on a board,
wherein the heat spreader includes a refrigerant encapsulation portion in which a fluid refrigerant is encapsulated.

3. An electronic apparatus comprising:
a board;
an electronic part mounted over the board;
a case that accommodates the board; and
a heat sink attached to the case to block an open side of the case for cooling the electronic part,
wherein the heat sink includes a base sheet metal having a flat plate shape, and a radiation fin bonded to a first surface of the base sheet metal,
wherein the radiation in includes:
a bonding plate portion having a fiat plate shape, and superposed and bonded to the first surface of the base sheet metal, and
a fin member installed upright with respect to the bonding plate portion, and
wherein the base sheet metal and the bonding plate portion are bonded to each other by fitting a convex portion, which is formed on one of the base sheet metal and the bonding plate portion, into a concave portion formed on a remaining one thereof through half-punch working.
